(19) United States
(12) Patent Application Publication
(10) Pub. No.: US 2009/0137106 A1
(43) Pub. Date: May 28, 2009

(54) USING ION IMPLANTATION TO CONTROL TRENCH DEPTH AND ALTER OPTICAL PROPERTIES OF A SUBSTRATE

(76) Inventor: Peter D. Nunan, Monte Serono, CA (US)

Correspondence Address: Scott Faber, Esq.;Varian Semiconductor Equipment Associates, Inc, 35 Dory Road, Gloucester, MA, 01930, US

(21) Appl. No.: 11/945,332

(22) Filed: Nov. 27, 2007

(51) Int. Cl. H01L 21/425

(52) U.S. Cl. 438/524; 257/E21.473

(57) ABSTRACT

A method for using ion implantation to create a precision trench in a mask or semiconductor substrate and to alter the optical properties of a mask or semiconductor substrate. In one embodiment, the method may include providing a semiconductor substrate or a mask, forming a damage layer in semiconductor substrate or the mask via ion implantation; wherein the damage layer is formed to a desired depth of the trench; etching the semiconductor substrate or mask to create the trench to the desired depth. In another embodiment, ion implantation is used to alter the optical properties of a mask.

### BACKGROUND

1. Technical Field

This disclosure relates generally to semiconductor mask formation for the fabrication of semiconductor devices, and more particularly, to a method for using ion implantation to control the depth of a trench and to alter the optical properties of a substrate.

2. Background Art

During the fabrication of semiconductor substrates, or chrome-less phase shift masks or reticles, the control of a depth of a trench is critical. Currently, the trench depth is controlled by time in a reactive ion etcher (RIE) chamber. Therefore, the uniformity of the trenches across the reticle or semiconductor substrate, and the depth of those trenches, is determined by the uniformity of the etcher as well as the micro loading effects of the mask design. Because the depth of the trench is primarily controlled by the amount of time the substrate is left in the RIE chamber, this can result in trenches that are not at a precise desired depth.

In addition, during fabrication of semiconductor substrates, or chrome-less phase shift masks or reticles, controlling the optical properties of the substrate or mask is important. The optical properties can affect how the mask is formed, i.e., if the optical properties are altered, a mask could be created with a different pattern than was intended. Controlling these optical properties is currently done by depositing a film on the substrates, rather than changing the optical properties of the substrates themselves. This deposition process is disadvantageous because it can leave dust or particles on the surface and therefore the mask that is created may not be the precise pattern that is desired.

While ion-implantation methods have been used in the art for various applications, ion-implantation has not been used to create precise trenches in semiconductor substrates or masks, or to alter the optical properties of a substrate or mask. For example, U.S. Pat. No. 7,008,729 (Tsai et. al.) discloses the use of ion-implantation, but does not disclose using the ion-implanting process to control the depth of a trench. Moreover, Tsai et al. does not disclose the unique relationship between the ion-implantation, the damage layer and the resulting trench depth. Tsai et al. further does not disclose using ion implantation to alter the optical properties of a substrate.

### SUMMARY

The present disclosure provides a method for using ion implantation to create a precision trench in a mask or semiconductor substrate, and to alter the optical properties of a substrate.

In a first aspect, the disclosure provides a method for controlling a depth of a trench in a mask, the method comprising: providing a semiconductor substrate, wherein the semiconductor substrate has a mask thereover; forming a damage layer in at least a portion of the mask via ion implantation; wherein the damage layer is formed to a desired depth of the trench; and etching the mask to create the trench to the desired depth.

In a second aspect, the disclosure provides a method for altering the optical properties of a substrate, the method comprising: providing a semiconductor substrate, wherein the semiconductor substrate has a mask thereover; ion implanting at least a portion of the mask to alter the optical properties of at least a portion of the mask.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a semiconductor substrate and mask during ion implantation.

FIG. 2 shows a semiconductor substrate and mask after ion implantation.

FIG. 3 shows a semiconductor substrate and mask after ion implantation and etching.

FIGS. 4-6 show the process of FIGS. 1-3 where the angle of incident has been changed.

FIG. 7 shows a semiconductor substrate and mask during ion implantation.

FIG. 8 shows a semiconductor substrate and mask after ion implantation where the optical properties are altered.

FIG. 9-10 show the process of FIGS. 7-8 where the angle of incident has been changed.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

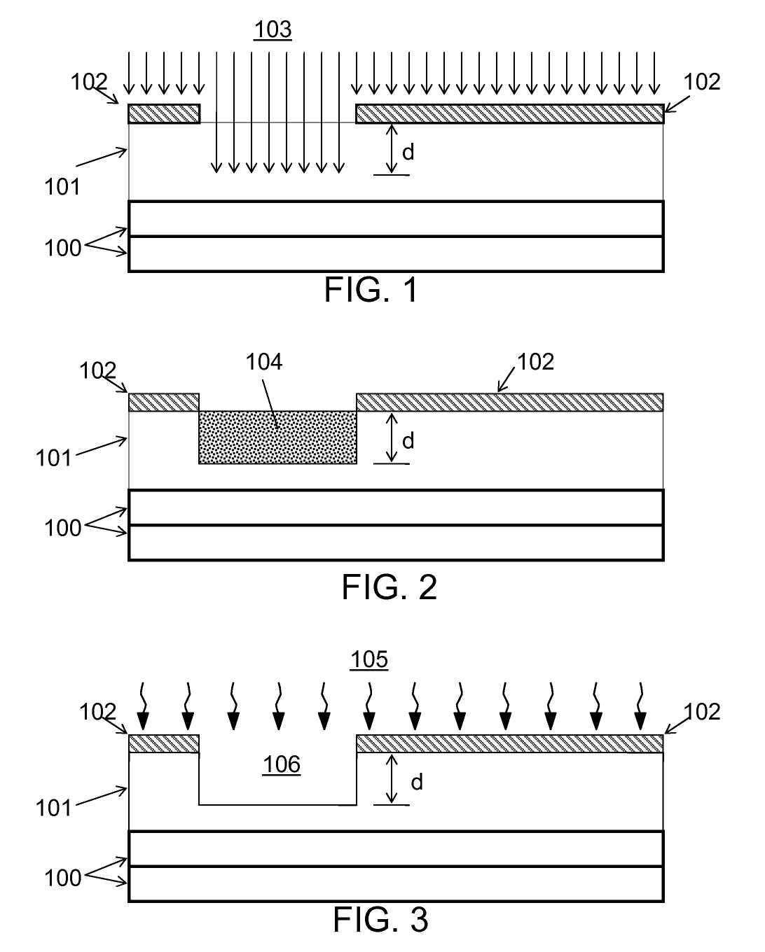

As can be seen in FIG. 1, a semiconductor substrate 100 is provided. Although only two layers are shown in FIG. 1, semiconductor substrate 100 can include a single layer, or a plurality of layers. In this embodiment, semiconductor substrate has a mask 101 thereover. The mask material can be quartz, or any other now known, or later developed, mask material, such as molybdenum silicide (MoSi).

Ion implantation (illustrated by arrows 103) is directed to the area where a trench is desired, shown as area 104 in FIG. 2, through the use of a blocking layer 102. Blocking layer 102 can include any now known or later developed blocking material, i.e., material that has a different etch rate than the material it is blocking. Blocking layer 102 prevents the ion implantation from bombarding the areas of the substrate which are covered by the blocking layer 102, and allows the ion implantation to bombard the desired region. Blocking layer 102 can be removed, if desired, before or after the etching step.

Ion implantation is a standard technique for introducing conductivity-altering impurities into semiconductor wafers. In a conventional beamline ion implantation system, a desired impurity material is ionized in an ion source, the ions are accelerated to form an ion beam of prescribed energy, and the ion beam is directed at the surface of a semiconductor wafer. Energetic ions in the beam penetrate into the bulk of the semiconductor material and are embedded into the crystalline lattice of the semiconductor material.

A user sets the parameters of the ion implantation device to implant so that the ions penetrate to a certain depth, d. As shown in FIG. 2, the ion implantation creates a damage layer 104 in mask layer 101 such that the peak of the damage layer is approximately the desired depth, d, of the desired trench. One of ordinary skill in the art will understand that the parameters of the ion implantation device can include, but are not limited to, which species can be used, which energy level can be used, and which incident angle is used.

For example, the species used can be one or more of the following: hydrogen, helium, boron, carbon, oxygen, fluorine, neon, silicon, phosphorus, argon, germanium, arsenic, indium or xenon. The energy level may be in the range of, for example, approximately 1-3000 KeV.

As shown in FIG. 3, after the ion implantation creates a damage layer 104 (shown in FIG. 2) in the mask 101, the mask 101 is etched (illustrated by arrows 105). Because damaged substrates etch faster than undamaged substrates, a trench 106 will be formed. The depth, d, of trench 106 will be substantially the same as the depth of the damage layer created by the ion implantation. The depth of the trench, d, may be in the range of, for example, approximately 50-500 nanometers. Moreover, the trench 106 will be at a precise desired depth, as opposed to the prior methods of forming trenches in the prior art.

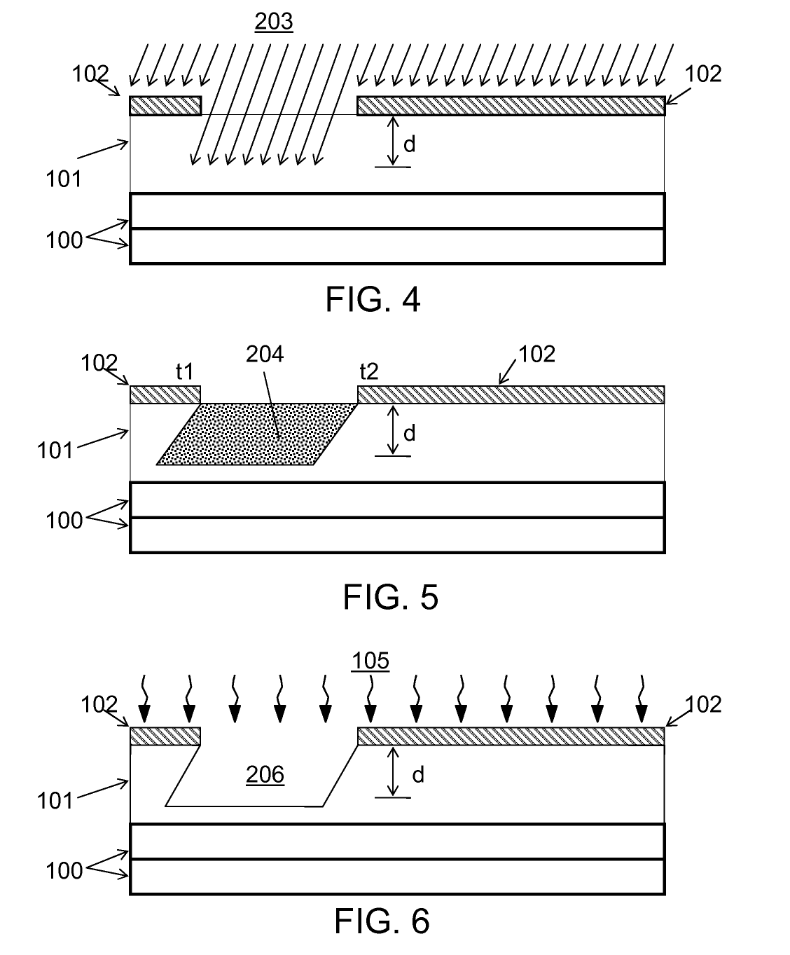

The incident angle, the angle at which the ions bombard the substrate, can also be altered to create trenches of various shapes. For example, if the ion implanter is set so that the ion beam bombards directly at the substrate surface, the damage layer, and accordingly the resulting trench, would be substantially rectangular, i.e., perpendicular to the substrate surface. However, if ion implanter is set so that the ion beams bombarded the substrate at an angle, the damage layer, and accordingly the resulting trench, would be substantially non-rectangular, i.e., either at a less than 90° angle, or more than 90° angle, with respect to the substrate surface. The formation of this angled non-rectangular trench 206 is illustrated in FIGS. 4-6. The process of FIGS. 4-6 is substantially similar to the process illustrated in FIGS. 3-5 except that the incident angle of the ion implantation 203 is altered as discussed above to form an angled damage area 204, which after etching, forms trench 206. One of skill in the art would understand that several different combinations of species, energy level and incident angle can be used to ensure the ion implantation penetrates to a certain depth and shape.

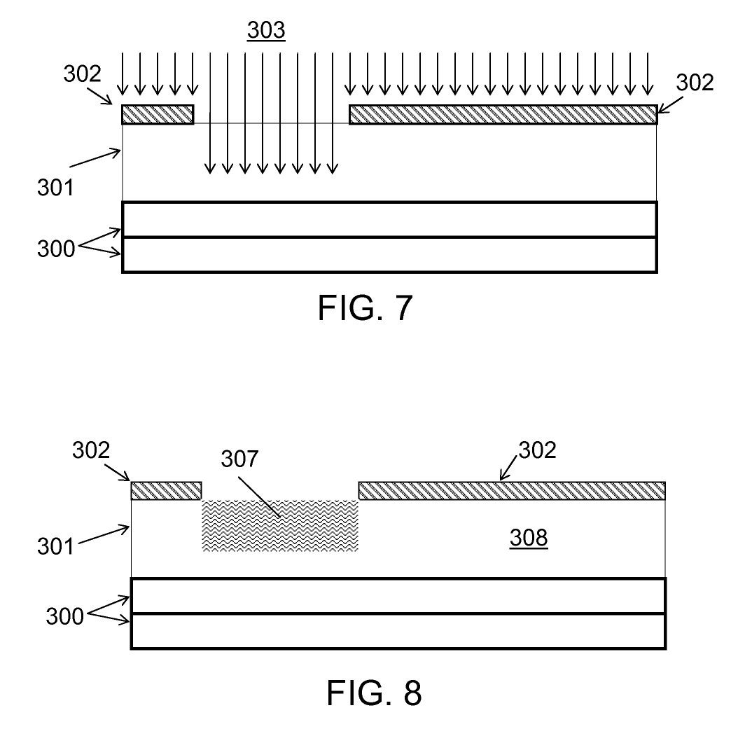

In another embodiment, the ion implantation is used to alter the optical properties of the mask. As can be seen in FIG. 7, a semiconductor substrate 300 is provided. Although only two layers are shown in FIG. 7, semiconductor substrate 300 can include a single layer, or a plurality of layers. In this embodiment, semiconductor substrate has a mask 301 thereover. The mask material can be quartz, or any other now known, or later developed mask material, such as molybdenum silicide (MoSi).

Ion implantation (illustrated by arrows 303) is directed to the area where the optical properties are to be altered, shown as area 307 in FIG. 8, through the use of a blocking layer 302. Blocking layer 302 can include any now known or later developed blocking material, i.e., material that has a different etch rate than the material it is blocking. Blocking layer 302 prevents the ion implantation from bombarding the areas of the substrate which are covered by the blocking layer 302, and allows the ion implantation to bombard the desired region. Blocking layer 302 can be removed, if desired, after the ion implantation process.

Referring to FIG. 8, after ion implantation, the area 307 that was implanted will have altered index of refraction (n) and/or extinction coefficient (k) as compared to the un-implanted areas, for example area 308.

One of skill in the art would understand that several various combinations of species, energy level and incident angle can be used to bombard the substrate to alter the optical properties of a specific area. For example, boron, phosphorous and fluorine are examples of species that can be used to bombard the substrate to alter the optical properties. For example, using fluorine as the species would lower the index of refraction of a quartz mask. The energy level can generally be in the range of 500 eV to 2 MeV to bombard the substrate to alter the optical properties.

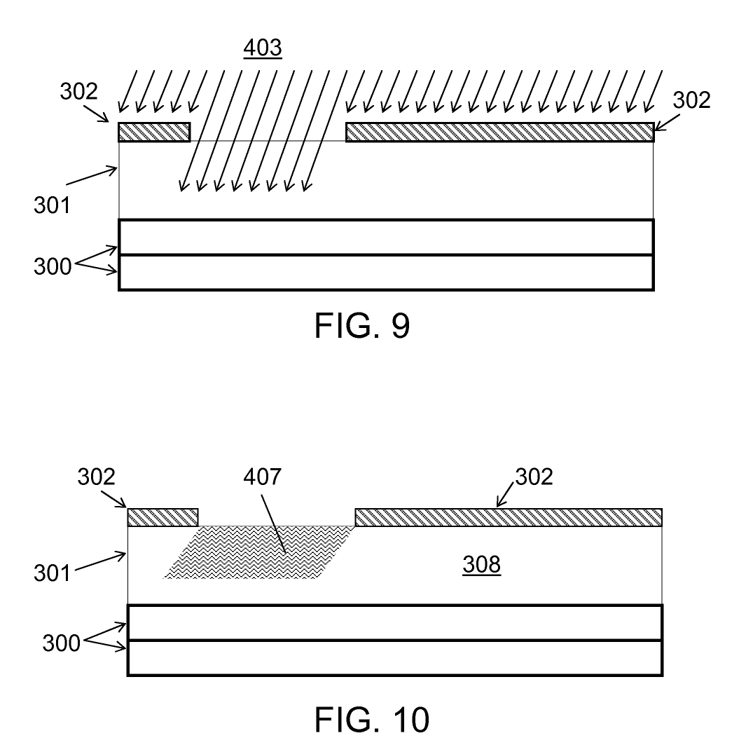

Also, as discussed above in connection with using ion implantation to create a depth, the incident angle of the ion implantation can be altered to create different shaped areas with altered optical properties. Referring to FIGS. 9-10, a process as described above in connection with FIGS. 7-8 is performed, with a different incident angle for the ion implantation. As shown in FIG. 9, non-rectangular area 407 of the substrate 301 is ion implanted, (illustrated by arrows 403), and as shown in FIG. 10, as a result of this ion implantation, non-rectangular area 407 has altered optical properties. It is understood that various different shaped areas with altered optical properties can result from varying the incident angle of the ion implantation.

The foregoing description of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of this disclosure as defined by the accompanying claims.

What is claimed is:

1. A method for controlling a depth of a trench in a mask, the method comprising:
providing a semiconductor substrate, wherein the semiconductor substrate has a mask thereover;
forming a damage layer in at least a portion of the mask via ion implantation; wherein the damage layer is formed to a desired depth of the trench; and
etching the mask to create the trench to the desired depth.

2. The method of claim 1, wherein the mask comprises one of the following materials: quartz or molybdenum silicide.

3. The method of claim 1, wherein the mask has a blocking layer thereover which allows at least a first portion of the mask to be implanted by the ion implantation; and prevents at least a second portion of the mask from being implanted by the ion implantation

4. The method of claim 1, wherein the trench depth is in the range of approximately 50-500 nanometers.

5. The method of claim 1, wherein the trench is formed at a precise depth.

6. The method of claim 1, wherein the ion implantation utilizes a species selected from the group consisting of: hydrogen, helium, boron, carbon, oxygen, fluorine, neon, silicon, phosphorus, argon, germanium, arsenic, indium or xenon.

7. The method of claim 1, wherein the ion implantation uses energy in the range of approximately 1-3000 KeV.

8. The method of claim 1, wherein an incident angle of the ion implantation is altered to create a non-rectangular trench.

9. A mask including a trench formed by the method of claim 1.

10. A method to alter the optical properties of a mask, the method comprising:
providing a semiconductor substrate, wherein the semiconductor substrate has a mask thereover; and
ion implanting at least a portion of the mask to alter the optical properties of at least a portion of the mask.

11. The method of claim 10, wherein the optical properties are one or more of the following: index of refraction and extinction coefficient.

12. The method of claim 10, wherein the mask has a blocking layer thereover, which allows at least a first portion of the mask to be implanted by the ion implantation; and prevents at least a second portion of the mask from being implanted by the ion implantation, wherein only the optical properties of the at least a first portion of the mask are altered.

13. The method of claim 10, wherein the ion implantation utilizes a species selected from the group consisting of: boron, fluorine, and phosphorus.

14. The method of claim 10, wherein the ion implantation uses energy in the range of approximately 500 eV to 2 MeV.

15. The method of claim 10, wherein an incident angle of the ion implantation is altered such that the portion of the mask that has altered optical properties is of a non-rectangular shape.

16. A mask formed by the method of claim 10, wherein at least a portion of the mask has altered optical properties.
